(19) United States
(12) Patent Application Publication
(10) Pub. No.: US 2025/0022995 A1
(43) Pub. Date: Jan. 16, 2025

(54) LIGHT-EMITTING DEVICE PACKAGES

(71) Applicant: Samsung Electronics Co., Ltd., Suwon-si (KR)

(72) Inventors: Ilseop Won, Suwon-si (KR); Changhoon Kwak, Suwon-si (KR); Chulsoo Yoon, Suwon-si (KR); DONGSOO LEE, Suwon-si (KR); Seunggyun Jung, Suwon-si (KR); Sujong Han, Suwon-si (KR)

(21) Appl. No.: 18/772,193

(22) Filed: Jul. 14, 2024

(30) Foreign Application Priority Data
Jul. 14, 2023 (KR) 10-2023-0092037
Apr. 4, 2024 (KR) 10-2024-0046213

(51) Int. Cl. H01L 33/60; H01L 25/075; H01L 33/62

(52) U.S. Cl. CPC H01L 33/60; H01L 25/0753; H01L 33/62

(57) ABSTRACT

A light-emitting device package includes a circuit board, a light-emitting device mounted on the circuit board, a reflective sheet disposed on the circuit board, the reflective sheet including an opening penetrating through the reflective sheet, wherein the light-emitting device is disposed within the opening, an inclined portion surrounding the opening when viewed in a plan view, and being inclined at a first angle with respect to an upper surface of the circuit board, and a flat extension portion surrounding the inclined portion when viewed in a plan view, and being parallel to the upper surface of the circuit board, and a diffuser plate disposed at a first vertical distance from the upper surface of the circuit board. An air gap is disposed between the upper surface of the circuit board and the flat extension portion.

### CROSS-REFERENCE TO RELATED APPLICATION

This application is based on and claims priority under 35 U.S.C. § 119 to Korean Patent Application No. 10-2023-0092037, filed on Jul. 14, 2023, and Korean Patent Application No. 10-2024-0046213, filed on Apr. 4, 2024, in the Korean Intellectual Property Office, the entire disclosures of both of which are incorporated by reference herein.

### BACKGROUND

The inventive concept relates to light-emitting device packages, and more particularly, to a light-emitting device package including a light-emitting device.

Demand for large areas and high quality of display devices is increasing. A backlight unit of display devices includes a light-emitting device package. In order to obtain an excellent display quality, light emitted by a light-emitting device is required to be emitted with uniform luminance over the entire large-area display device. A light-emitting device package used in a backlight unit includes light-emitting devices installed at regular intervals on a circuit board. However, light with a relatively low luminance is directed to an area between light-emitting devices, and thus dark spots or mura may be generated, leading to deterioration of optical performance and/or display quality.

### SUMMARY

The inventive concept provides a light-emitting device package capable of improving optical efficiency and preventing occurrence of luminance non-uniform elements such as dark spots.

According to an aspect of the inventive concept, there is provided a light-emitting device package including a circuit board, a light-emitting device mounted on the circuit board, a reflective sheet disposed on the circuit board, and a diffuser plate disposed at a first vertical distance from the upper surface of the circuit board. The reflective sheet includes an opening penetrating through the reflective sheet, wherein the light-emitting device is disposed within the opening, an inclined portion surrounding the opening when viewed in a plan view, and being inclined at a first angle with respect to an upper surface of the circuit board, and a flat extension portion surrounding the inclined portion when viewed in the plan view, and being parallel to the upper surface of the circuit board. An air gap is disposed between the upper surface of the circuit board and the flat extension portion.

According to another aspect of the inventive concept, there is provided a light-emitting device package including a circuit board, a reflective sheet disposed on the circuit board, the reflective sheet including a plurality of openings disposed apart from each other at a first interval in a first horizontal direction parallel to an upper surface of the circuit board and penetrating through the reflective sheet, a plurality of inclined portions respectively surrounding the plurality of openings when viewed in a plan view, wherein each of the plurality of inclined portions is inclined at a first angle with respect to the upper surface of the circuit board and the plurality of inclined portions are arranged apart from each other at a second interval in the first horizontal direction, and a flat extension portion surrounding the plurality of inclined portions when viewed in the plan view and being parallel to the upper surface of the circuit board, wherein the flat extension portion is spaced apart from the upper surface of the circuit board in a vertical direction perpendicular to the upper surface, a plurality of light-emitting devices mounted on the circuit board and respectively disposed within the plurality of openings of the reflective sheet, and a diffuser plate disposed at a first vertical distance from the upper surface of the circuit board.

According to another aspect of the inventive concept, there is provided a light-emitting device package including a circuit board, a plurality of light-emitting devices disposed on the circuit board and arranged in an array form, a reflective sheet disposed on an upper surface of the circuit board, and a diffuser plate disposed at a first vertical distance from the upper surface of the circuit board. The reflective sheet includes a plurality of openings penetrating through the reflective sheet, wherein the plurality of light-emitting devices are disposed within the plurality of openings, respectively, a plurality of inclined portions respectively surrounding the plurality of openings when viewed in a plan view, wherein each of the plurality of inclined portions is inclined at a first angle with respect to the upper surface of the circuit board, and a flat extension portion surrounding the plurality of inclined portions when viewed in the plan view and being parallel to the upper surface of the circuit board, wherein the flat extension portion is spaced apart from the upper surface of the circuit board in a vertical direction perpendicular to the upper surface. An air gap is disposed between the flat extension portion and the upper surface of the circuit board.

### BRIEF DESCRIPTION OF THE DRAWINGS

Embodiments will be more clearly understood from the following detailed description taken in conjunction with the accompanying drawings in which:

FIG. 1 is a plan view of a light-emitting device package according to example embodiments;

FIG. 2 is a cross-sectional view of a portion taken along line A-A′ of FIG. 1;

FIG. 3 is a cross-sectional view of a light-emitting device of FIG. 2;

FIG. 4 is a cross-sectional view of a light-emitting device package according to example embodiments;

FIG. 5 is a plan view of a light-emitting device package according to example embodiments;

FIGS. 6 and 7 are plan views of light-emitting device packages according to example embodiments;

FIG. 8 is a plan view of a light-emitting device package according to example embodiments;

FIG. 9 is a plan view of a light-emitting device package according to example embodiments;

FIGS. 10 through 12 are cross-sectional views illustrating a method of manufacturing a light-emitting device package according to example embodiments;

FIG. 13 illustrates optical images of light-emitting device packages according to example embodiments;

FIG. 14 is a graph showing luminances of the semiconductor device packages of FIG. 13;

FIG. 15 illustrates optical images showing dark spots of the semiconductor device packages of FIG. 13;

FIGS. 16 and 17 are graphs showing simulation results of respective far-field emission patterns of single chip packages;

FIG. 18 is a schematic perspective view of a backlight unit including a light-emitting device package according to example embodiments;

FIG. 19 is a schematic exploded perspective view of a display device including a light-emitting device package according to example embodiments; and

FIG. 20 is a schematic exploded perspective view of a bar-type illumination apparatus including a light-emitting device manufactured using a light-emitting device manufacturing method according to an example embodiment,

### DETAILED DESCRIPTION OF THE EMBODIMENTS

Embodiments will now be described fully with reference to the accompanying drawings. Like references refer to like elements throughout. Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

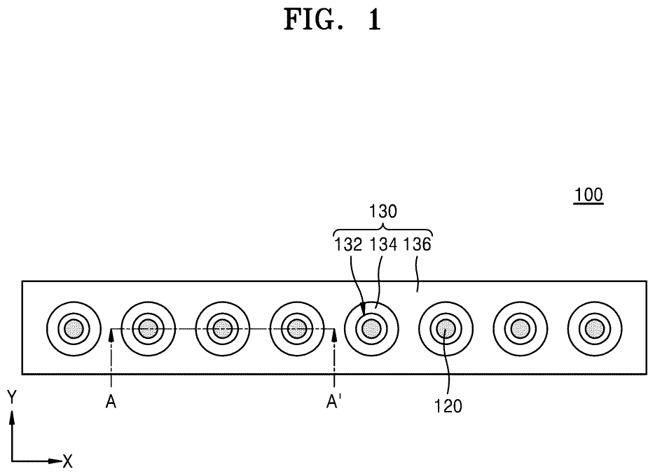

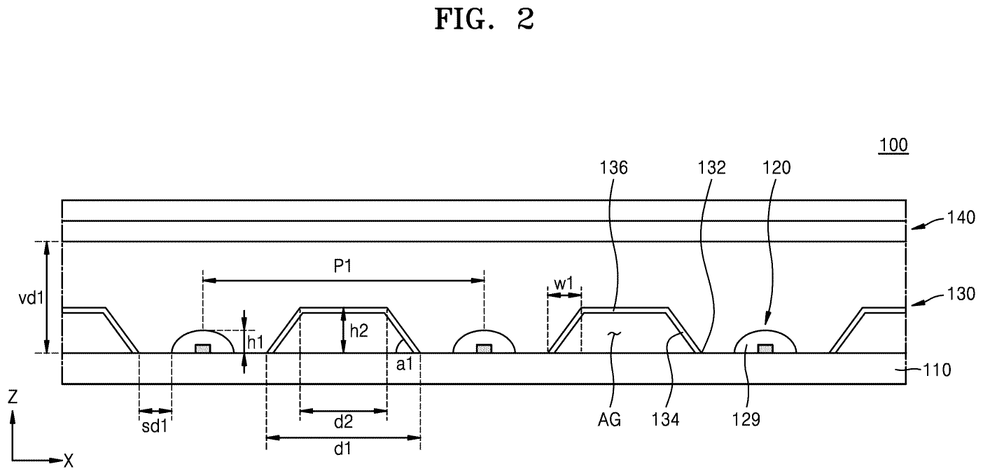

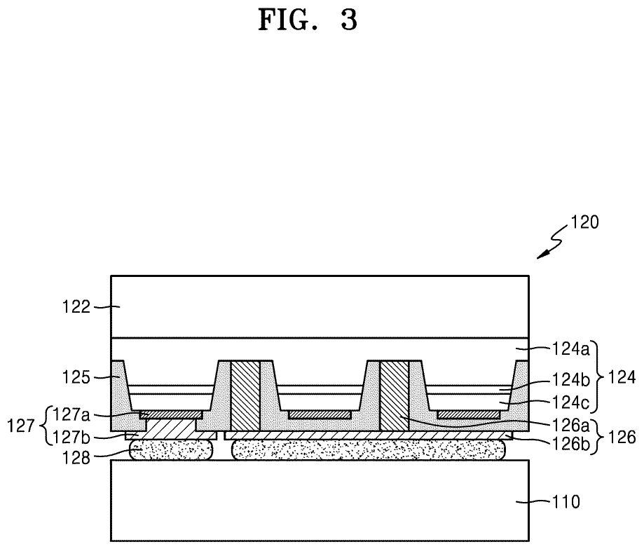

FIG. 1 is a plan view of a light-emitting device package 100 according to example embodiments. FIG. 2 is a cross-sectional view of a portion taken along line A-A′ of FIG. 1. FIG. 3 is a cross-sectional view of a light-emitting device 120 of FIG. 2.

Referring to FIGS. 1 and 2, the light-emitting device package 100 may include a circuit board 110, a light-emitting device 120, a reflective sheet 130, and a diffuser plate 140.

The circuit board 110 may extend with a certain length in a first horizontal direction X. The circuit board 110 may be a printed circuit board with circuit patterns formed inside and/or on the top. For example, the circuit board 110 may be formed in a stack structure including a metal base including, for example, aluminum, an insulating layer covering the metal base, and the circuit patterns provided on the insulating layer. For example, the circuit board 110 may be a metal copper clad laminate (MCCL). However, the structure of the circuit board 110 is not limited thereto.

A plurality of light-emitting devices 120 may be arranged to be spaced apart from each other on an upper surface of the circuit board 110 in the first horizontal direction X. The plurality of light-emitting devices 120 may be mounted on the circuit board 110 using a flip chip method.

As illustrated in FIG. 3, each of the plurality of light-emitting devices 120 may include a semiconductor substrate 122 and a light-emitting stack 124 disposed on the semiconductor substrate 122, and the light-emitting stack 124 may include a first conductivity type semiconductor layer 124a, an active layer 124b, and a second conductivity type semiconductor layer 124c arranged sequentially. Although not shown in the drawings, a buffer layer (not shown) may be further formed between the semiconductor substrate 122 and the first conductivity type semiconductor layer 124a.

A first electrode 126 connected to the first conductivity type semiconductor layer 124a, and a second electrode 127 connected to the second conductivity type semiconductor layer 124c may be further formed. The first electrode 126 may include a connection electrode portion 126a such as a conductive via penetrating through the second conductivity type semiconductor layer 124c and the active layer 124b, and a first electrode pad 126b connected to the connection electrode portion 126a. An upper surface of the connection electrode portion 126a may contact the first conductivity type semiconductor layer 124a, and the first electrode pad 126b may contact the connection electrode portion 126a and a portion of the adhesive layer 128. The connection electrode portion 126a may be surrounded by an insulating layer 125 and electrically separated from the active layer 124b and the second conductivity type semiconductor layer 126c. For example, the insulating layer 125 may contact side surfaces of the connection electrode portion 126a, and may be provided between the connection electrode portion 126a and the active layer 124b and the second conductivity type semiconductor layer 126c. The first electrode 126 may be electrically connected to the first conductivity type semiconductor layer 124a through the connection electrode portion 126a extending to an inside of the light-emitting stack 124. The connection electrode portion 126a may be disposed in an area where the light-emitting stack 124 is etched. The second electrode 127 may include an ohmic contact layer 127a on the second conductivity type semiconductor layer 124c, and a second electrode pad 127b. The second electrode pad 127b may contact the ohmic contact layer 127a and a portion of the adhesive layer 128. Each of the connection electrode portion 126a and the ohmic contact layer 127a may include a single-layered or multi-layered structure of a conductive material having ohmic properties with respect to the first and second conductivity type semiconductor layers 124a and 124c, respectively. For example, each of the connection electrode portion 126a and the ohmic contact layer 127a may be formed through a process such as deposition or sputtering of one or more of materials such as Ag, Al, Ni, Cr, and transparent conductive oxide.

The first and second electrode pads 126b and 127b may be connected to the connection electrode portion 126a and the ohmic contact layer 127a, respectively, and may function as external terminals of the plurality of light-emitting devices 120. For example, the first and second electrode pads 126b and 127b may be formed of or include Au, Ag, Al, Ti, W, Cu, Sn, Ni, Pt, Cr, NiSn, TiW, AuSn, or a eutectic alloy thereof.

Although a detailed structure of the plurality of light-emitting devices 120 has been described with reference to FIG. 3, a structure and a shape of the plurality of light-emitting devices 120 are not limited to those illustrated in FIG. 3. For example, unlike what is shown in FIG. 3, V-pits or irregularities may be formed between the semiconductor substrate 122 and the light-emitting stack 124, and the light-emitting stack 124 may have a plurality of nano light-emitting structures. In this way, the structure and shape of the plurality of light-emitting devices 120 may vary.

The plurality of light-emitting devices 120 may further include a transparent resin layer 129 covering an upper surface and sidewalls of the semiconductor substrate 122.

The transparent resin layer 129 may include a resin in which a phosphor is dispersed or a resin that does not contain a phosphor. For example, the transparent resin layer 129 may include a phosphor film or a silicon resin. According to embodiments, the transparent resin layer 129 may include a phosphor film in which phosphor particles are uniformly dispersed at a predetermined concentration. The phosphor particles may be a wavelength conversion material for converting the wavelength of the light emitted from the plurality of light-emitting devices 120. For example, when the plurality of light-emitting devices 120 are blue light-emitting devices that emit light with a peak intensity in a blue wavelength range (for example, a 415 to 495 nm range), the transparent resin layer 129 may include a phosphor film including a yellow color, a green color, a red color, or an orange color, or a combination thereof. Accordingly, white light may be emitted through the transparent resin layer 129.

According to embodiments, the phosphor may have various compositions and colors, such as oxides, silicates, nitrides, and fluorides. For example, in a light source module used in a backlight unit, β-SiAION:Eu²⁺ (green), (Ca,Sr) AlSiN₃:Eu²⁺ (red), La₃Si₆N₁₁:Ce³⁺ (yellow), K₂SiF₆:Mn⁴⁺ (red), SrLiAl₃N₄:Eu (red), Ln₄₋ₓ (Eu_{z}M_{1-z})ₓSi_{12-y}Al_{y}O_{3+x+y}N_{18-x-y} (0.5≥x≥3, 0<z<0.3, 0<y≥4) (red), K₂TiF₆:Mn₄⁺ (red), NaYF₄:Mn₄⁺ (red), NaGdF₄:Mn₄⁺ (red), or the like may be used as the phosphor. However, the type of the phosphor is not limited thereto.

According to some embodiments, a side encapsulation layer may be disposed to surround at least one side of each of a plurality of light-emitting stacks 124. According to embodiments, the side encapsulation layer may be composed of a resin in which one or more types of scattering particles selected from the group consisting of TiO₂, ZnO, silica, Al₂O₃, and MgO are dispersed. The side encapsulation layer may function so that light emitted through the side surfaces of the plurality of light-emitting devices 120 is scattered by the side encapsulation layer and directed upwards over the plurality of light-emitting devices 120.

In other embodiments, the transparent resin layer 129 may include a resin containing no phosphor. In this case, a wavelength conversion material such as quantum dots may be disposed on the outside of the light-emitting device package 100 (or at an upper portion of the light-emitting device package 100). The quantum dots may have a core-shell structure by using a Groups III-V or II-VI elements-containing compound semiconductor, and may have a core such as CdSe or InP and a shell such as ZnS or ZnSe. Furthermore, the quantum dots may have a ligand for stabilization of the core and the shell. The quantum dots may be disposed on the light-emitting device package 100 by being contained in an encapsulant, or alternatively, may be manufactured in a film type and attached onto the light-emitting device package 100 or onto a light guide plate (not shown).

The plurality of light-emitting devices 120 may be mounted on the circuit board 110 via an adhesive layer 128. The adhesive layer 128 may be, for example, a solder layer, and first and second electrode pads 126b and 127b of the plurality of light-emitting devices 120 may be electrically connected to circuit patterns arranged on or inside the circuit board 110 by the adhesive layer 128.

As illustrated in FIG. 2, the plurality of light-emitting devices 120 may be arranged to be spaced apart from each other with a first pitch P1 in the first horizontal direction X. For example, a center point of one light-emitting device 120 and a center point of another light-emitting device 120 adjacent thereto may be spaced apart by the first pitch P1. According to embodiments, the first pitch P1 may range from about 3 mm to about 100 mm. However, embodiments are not limited thereto.

Each of the plurality of light-emitting devices 120 may have a first height h1 in a vertical direction Z from an upper surface of the circuit board 110. The first height h1 may indicate a distance from an upper surface of the circuit board 110 to the upper surface of the transparent resin layer 129 in the vertical direction Z. In some embodiments, the first height h1 may range from about 0.1 mm to about 10 mm. However, embodiments are not limited thereto.

A reflective sheet 130 may be disposed on the circuit board 110. The reflective sheet 130 may have a shape extending in a direction in which the circuit board 110 extends (e.g., the first horizontal direction X).

The reflective sheet 130 may include a plurality of openings 132 penetrating through the reflective sheet 130. The plurality of openings 132 may be arranged to be spaced apart from each other at a first interval d1 in the first horizontal direction X. The first interval d1 may indicate a shortest distance between one opening 132 and an opening 132 adjacent thereto.

The plurality of openings 132 may be disposed at positions corresponding to the plurality of light-emitting devices 120, respectively. The plurality of light-emitting devices 120 may be disposed within the plurality of openings 132, respectively. The plurality of openings 132 may be arranged to be spaced apart from the plurality of light-emitting devices 120 at a first separation distance sd1, and the first separation distance sd1 may be in the range of about 0.5 mm to about 1 mm.

The reflective sheet 130 may further include a plurality of inclined portions 134 and a plurality of flat extension portions 136. The plurality of inclined portions 134 may be arranged to be spaced apart from each other at a second interval d2 in the first horizontal direction X. The second interval d2 may indicate a shortest distance between one inclined portion 134 and an inclined portion 134 adjacent thereto.

In some embodiments, each of the plurality of inclined portions 134 may be arranged to surround each of the plurality of openings 132 when viewed in a plan view. For example, the plurality of openings 132 may have a circular planar shape, and the plurality of inclined portions 134 may have a circular planar shape. Each of the plurality of inclined portions 134 may have a shape that is concentric with a corresponding opening 132.

In some embodiments, the plurality of inclined portions 134 may be inclined at a first inclination angle a1 with respect to the upper surface of the circuit board 110. In some embodiments, the first inclination angle a1 may range from about 5 degrees to about 70 degrees. The plurality of inclined portions 134 may allow light emitted laterally from a light-emitting device 120 disposed in an opening 132 to be reflected by an inclined surface of an inclined portion 134 and directed upward.

The flat extension portion 136 may be arranged to surround the plurality of inclined portions 134 when viewed in a plan view. The flat extension portion 136 may indicate a portion of the reflective sheet 130 extending in a direction parallel to the upper surface of the circuit board 110. The flat extension portion 136 may be disposed apart from the upper surface of the circuit board 110 in the vertical direction Z perpendicular to the upper surface of the circuit board 110.

As the flat extension portion 136 is disposed to be spaced apart from the upper surface of the circuit board 110 in the vertical direction Z perpendicular to the upper surface of the circuit board 110, an air gap AG may be disposed between the reflective sheet 130 and the circuit board 110. The air gap AG may be disposed between the reflective sheet 130 and the circuit board 110, and may refer to an empty space filled with air without any other material layer or sealing layer therein. The term “air,” as discussed herein, may refer to atmospheric air, or other gases that may be present during the manufacturing process.

In some embodiments, the flat extension portion 136 may have a second height h2 from the upper surface of the circuit board 110. The second height h2 may indicate a distance from the upper surface of the circuit board 110 to an upper surface of the flat extension portion 136 in the vertical direction Z. In some embodiments, the second height h2 may range from about 0.1 mm to about 50 mm. However, embodiments are not limited thereto. According to some embodiments, the second height h2 may range from about 0.4 mm to about 10 mm.

In some embodiments, as shown in FIG. 2, the second height h2 of the flat extension portion 136 may be greater than the first height h1 of the plurality of light-emitting devices 120. In other embodiments, the second height h2 of the flat extension portion 136 may be less than the first height h1 of the plurality of light-emitting devices 120.

In some embodiments, the reflective sheet 130 may include a biaxially oriented polyester film. In some embodiments, the reflective sheet 130 may include biaxially oriented polyethylene terephthalate. According to some embodiments, the reflective sheet 130 may include reflective metal foil.

In some embodiments, the reflective sheet 130 may have a reflectivity of about 80% to about 100% and a transmittance of about 0% to about 20%. According to some embodiments, the reflective sheet 130 may have a reflectivity of about 90% to about 100% and a transmittance of about 0% to about 10%.

The reflective sheet 130 may be attached onto the circuit board 110 by an adhesive, and, for example, the adhesive may be interposed between at least a portion of the inclined portion 134 and the circuit board 110.

The light-emitting device package 100 may further include a diffuser plate 140 disposed at a higher level than the circuit board 110. The diffuser plate 140 may be disposed at a first vertical distance vd1 from the upper surface of the circuit board 110. The diffuser plate 140 may be configured so that the light emitted from the plurality of light-emitting devices 120 is scattered through the diffuser plate 140 and uniform light is transmitted to a display device. The first vertical distance vd1 between the diffuser plate 140 and the circuit board 110 may be in the range of about 1 to about 300 mm.

The diffuser plate 140 may be arranged over the circuit board 110 such that the first vertical distance vd1 between the diffuser plate 140 and the circuit board 110 has a specific relationship with the first pitch P1 of the plurality of light-emitting devices 120.

According to some embodiments, a ratio of the first pitch P1 of the plurality of light-emitting devices 120 to the first vertical distance vd1 between the diffuser plate 140 and the circuit board 110 may be in the range of about 2 to about 10. For example, the first pitch P1 of the plurality of light-emitting devices 120 may be in the range of about 2 times to about 10 times the first vertical distance vd1 between the diffuser plate 140 and the circuit board 110.

In some embodiments, the first inclination angle a1 of the plurality of inclined portions 134 of the reflective sheet 130 may be formed to have a specific relationship with the first vertical distance vd1 between the diffuser plate 140 and the circuit board 110 and/or the first pitch P1 of the plurality of light-emitting devices 120. The ratio of the first pitch P1 of the plurality of light-emitting devices 120 to the first vertical distance vd1 between the diffuser plate 140 and the circuit board 110 may be in the range of about 2 to about 10. In this case, the first inclination angle a1 of the plurality of inclined portions 134 may have a value of 25 degrees±15 degrees. For example, the first inclination angle a1 may be selected in the range of about 10 degrees to about 40 degrees.

In other embodiments, the ratio of the first pitch P1 of the plurality of light-emitting devices 120 to the first vertical distance vd1 between the diffuser plate 140 and the circuit board 110 may be in the range of about 0.5 to about 1.5. For example, the first pitch P1 of the plurality of light-emitting devices 120 may be in the range of about 0.5 to about 1.5 times the first vertical distance vd1 between the diffuser plate 140 and the circuit board 110. In this case, the first inclination angle a1 of the plurality of inclined portions 134 may have a value of 45 degrees+25 degrees. For example, the first inclination angle a1 may be selected in the range of about 20 degrees to about 70 degrees.

In some embodiments, a first width w1 of the plurality of inclined portions 134 of the reflective sheet 130 may be formed to have a specific relationship with the first pitch P1 of the plurality of light-emitting devices 120. For example, as shown in FIG. 2, the first width w1 of the plurality of inclined portions 134 may indicate a distance from a side wall of the opening 132 to a boundary line between the inclined portion 134 and the flat extension portion 136. The first width w1 of the plurality of inclined portions 134 may have a range of about 5% to about 30% of the first pitch P1 of the plurality of light-emitting devices 120.

The first vertical distance vd1 between the diffuser plate 140 and the circuit board 110, the first pitch P1 of the plurality of light-emitting devices 120, and the first inclination angle a1 of the plurality of inclined portions 134 of the reflective sheet 130 may be values determined so that the light emitted to the outside of the light-emitting device package 100 through the diffuser plate 140 is uniformly (for example, without non-uniform elements such as dark spots) transmitted to the display device. For example, even when a portion of the light directed upward from the plurality of light-emitting devices 120 is reflected through the diffuser plate 140, the portion may be reflected again through the inclined portion 134 and the flat extension portion 136 of the reflective sheet 130 and directed upward, and thus the light emitted from the plurality of light-emitting devices 120 may be transmitted to the display device without light loss.

In general, a light-emitting device package used as a backlight unit of a display device includes light-emitting devices spaced apart from each other at regular intervals on a circuit board. However, light with a relatively low luminance may be directed to an area between light-emitting devices, and thus dark spots may be generated, leading to deterioration of optical performance and/or display quality.

However, according to light-emitting device packages according to example embodiments, light may be emitted by the inclined portion 134 and the flat extension portion 136 of the reflective sheet 130 disposed on the circuit board 110 with high luminance, and occurrence of luminance non-uniform elements such as dark spots may be prevented. Therefore, backlight units and display devices employing the light-emitting device package 100 may have excellent optical quality.

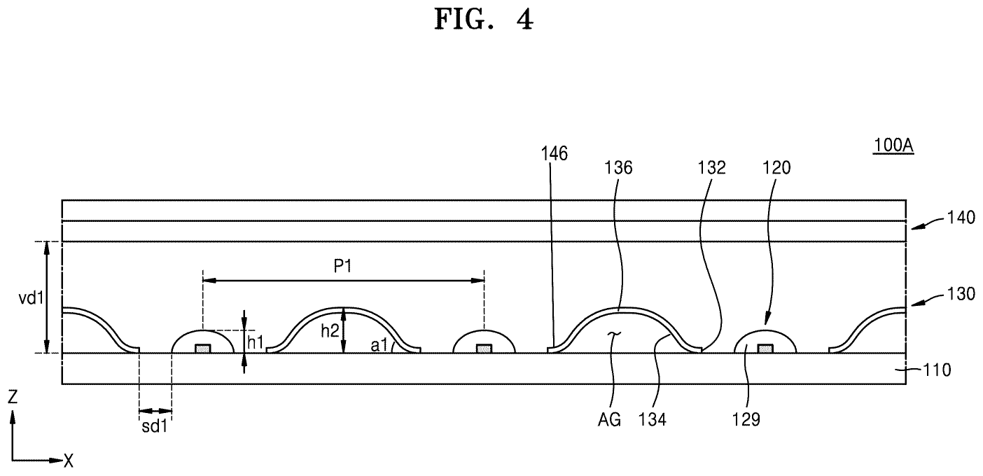

FIG. 4 is a cross-sectional view of a light-emitting device package 100A according to example embodiments. Duplicative descriptions will not be repeated.

Referring to FIG. 4, a plurality of inclined portions 134 may have a first inclination angle a1 that varies depending on a distance from the upper surface of the circuit board 110. For example, each of the plurality of inclined portions 134 may have a portion extending horizontally in a lateral direction in an area adjacent to the upper surface of the circuit board 110, and the first inclination angle a1 may increase in a direction away from the upper surface of the circuit board 110. In addition, each of the plurality of inclined portions 134 has a first inclination angle a1 that decreases in a direction toward a flat extension portion 146, and may have a portion extending horizontally in a lateral direction in an area adjacent to the flat extension portion 146. A reflective sheet 130 may have a shape in which a plurality of inclined portions 134 and a flat extension portion 146 are gently connected to each other. For example, the reflective sheet 130 may have a curved shape at the junction between the plurality of inclined portions 134 and the flat extension portion 146.

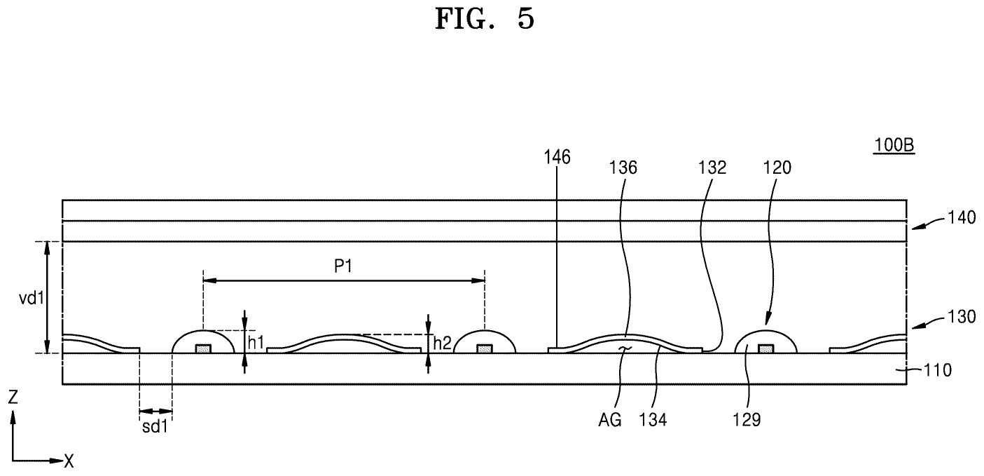

FIG. 5 is a plan view of a light-emitting device package 100B according to example embodiments. Duplicative descriptions will not be repeated.

Each of a plurality of light-emitting devices 120 may have a first height h1 in the vertical direction Z from an upper surface of the circuit board 110. In some embodiments, a flat extension portion 136 may have a second height h2 from the upper surface of the circuit board 110. The second height h2 of the flat extension portion 136 may be less than the first height h1 of the plurality of light-emitting devices 120.

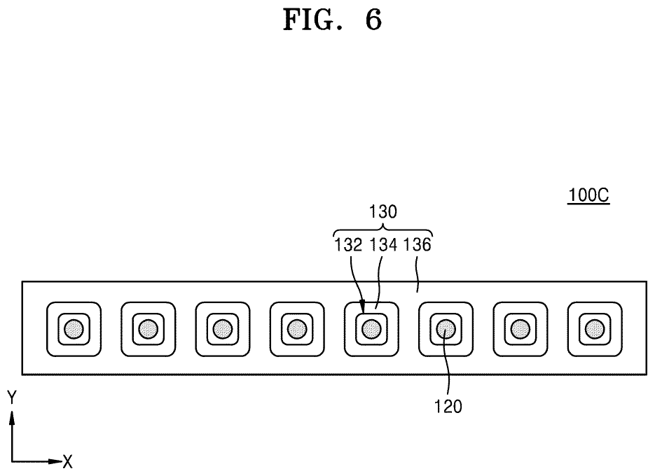

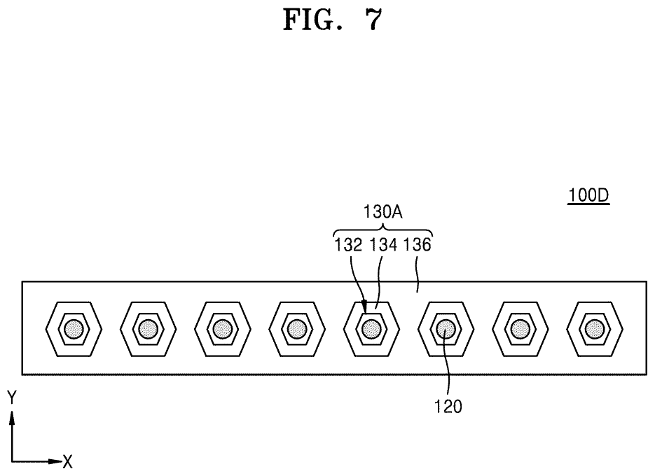

FIGS. 6 and 7 are plan views of light-emitting device packages 100C and 100D, respectively, according to example embodiments. Duplicative descriptions will not be repeated.

Referring to FIG. 6, a plurality of openings 132 of a reflective sheet 130 may each have a rounded rectangular planar shape. Each of a plurality of inclined portions 134 may also have a rounded rectangular planar shape. When viewed in plan view, the rounded rectangular planar shape of the plurality of openings 132 may be concentric with the rounded rectangular planar shape of the plurality of inclined portions 134.

Referring to FIG. 7, a plurality of openings 132 of a reflective sheet 130 may each have a hexagonal planar shape. Each of a plurality of inclined portions 134 may also have a hexagonal planar shape. When viewed in plan view, the hexagonal planar shape of the plurality of openings 132 may be concentric with the hexagonal planar shape of the plurality of inclined portions 134.

The planar shapes of the plurality of openings 132 and the plurality of inclined portions 134 of the reflective sheet 130 are not limited to those shown in FIGS. 6 and 7. According to some embodiments, each of the planar shapes of the plurality of openings 132 and the plurality of inclined portions 134 may have any of other shapes such as an oval, a square, a triangle, or a diamond. In each of these embodiments, the plurality of openings 132 may be concentric with the plurality of inclined portions 134.

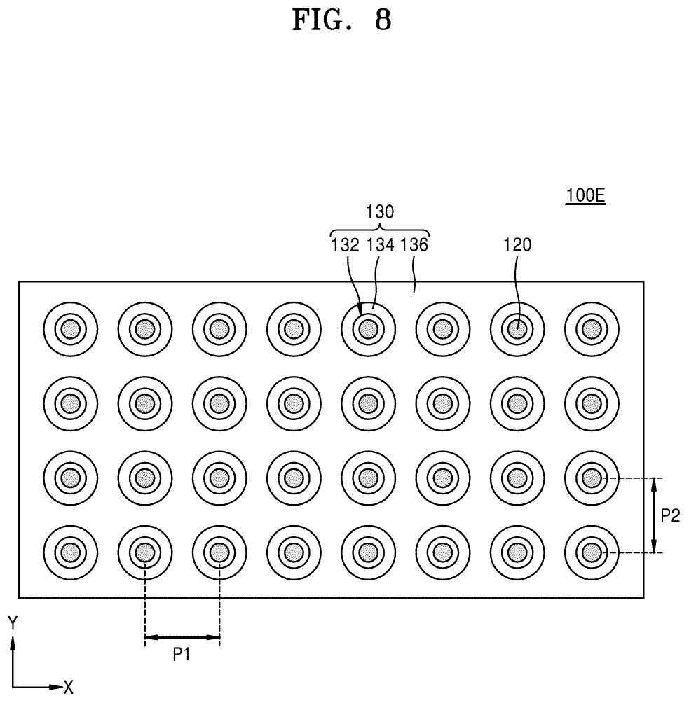

FIG. 8 is a plan view of a light-emitting device package 100E according to example embodiments. Duplicative descriptions will not be repeated.

Referring to FIG. 8, a plurality of light-emitting devices 120 may be arranged in a matrix or array form. For example, the plurality of light-emitting devices 120 may be arranged at a first pitch P1 in the first horizontal direction X and may be arranged at a second pitch P2 in a second horizontal direction Y. For example, each of the first pitch P1 and the second pitch P2 may range from about 3 mm to about 100 mm. However, embodiments are not limited thereto. According to some embodiments, the first pitch P1 may have a different value from the second pitch P2. For example, the first pitch P1 may be greater than the second pitch P2. As another example, the first pitch P1 may be less than the second pitch P2. According to some embodiments, the first pitch P1 may have a value that is the same as or similar to that of the second pitch P2.

A plurality of openings 132 of a reflective sheet 130 may be arranged in a matrix form or an array form, and may be arranged to surround the plurality of light-emitting devices 120, respectively, when viewed in a plan view. For example, each of the plurality of openings 132 may be concentrically arranged to surround a corresponding one of the plurality of light-emitting devices 120.

A plurality of inclined portions 134 of the reflective sheet 130 may be arranged in a matrix form or an array form, and may be arranged to surround the plurality of openings 132 and surround the plurality of light-emitting devices 120, respectively, when viewed in a plan view. For example, each of the plurality of inclined portions 134 may be concentrically arranged to surround a corresponding one of the plurality of openings 132 and a corresponding one of the plurality of light-emitting devices 120.

In FIG. 8, the plurality of openings 132 and the plurality of inclined portions 134 are illustrated as each having a circular planar shape. However, the technical idea of the inventive concept is not limited thereto, and each of the planar shapes of the plurality of openings 132 and the plurality of inclined portions 134 may have any of other shapes such as a rounded rectangle, a hexagon, an oval, a square, a triangle, or a diamond.

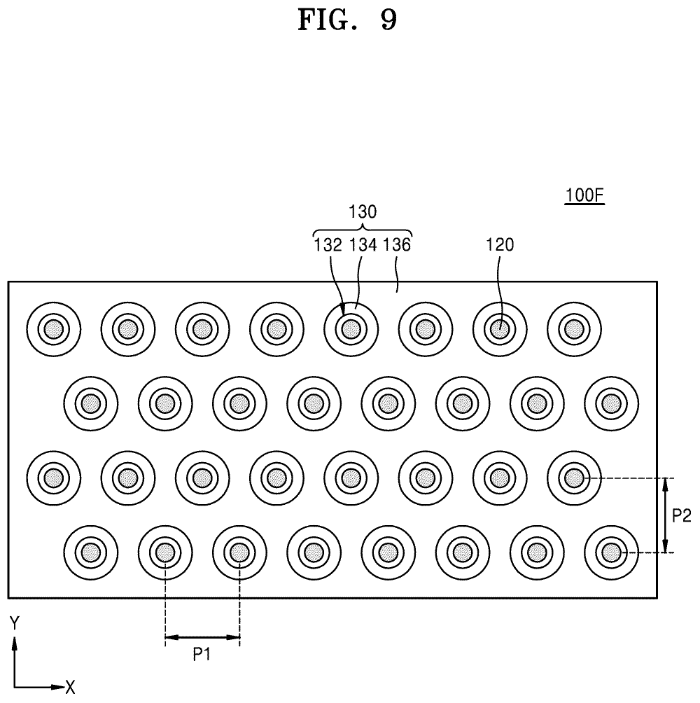

FIG. 9 is a plan view of a light-emitting device package 100F according to example embodiments.

Referring to FIG. 9, a plurality of light-emitting devices 120 may be arranged at a first pitch P1 in the first horizontal direction X, and may be arranged to be offset in the second horizontal direction Y and have a second pitch P2 in the second horizontal direction Y. For example, the plurality of light-emitting devices 120 may be arranged in a zigzag configuration or a staggered configuration. Each of the first pitch P1 and the second pitch P2 may range from about 3 mm to about 100 mm. According to some embodiments, the first pitch P1 may have a different value from the second pitch P2. For example, the first pitch P1 may be greater than the second pitch P2. As another example, the first pitch P1 may be less than the second pitch P2. According to some embodiments, the first pitch P1 may have a value that is the same as or similar to that of the second pitch P2.

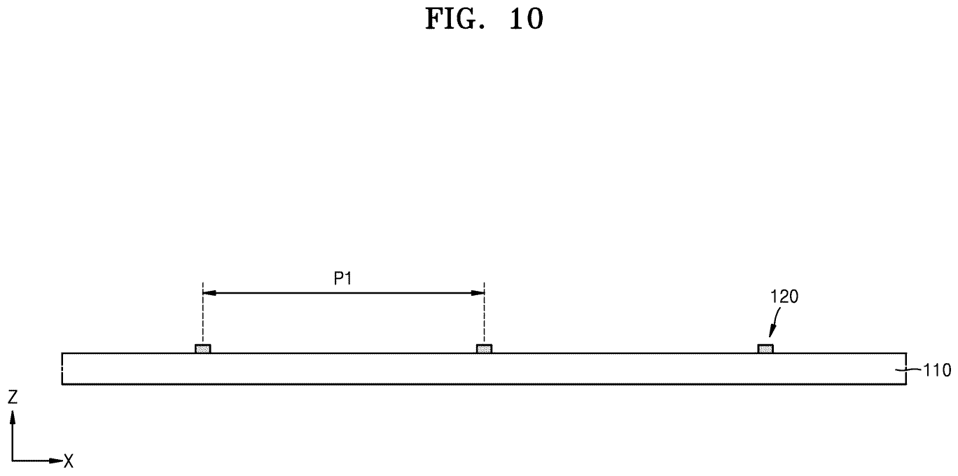

FIGS. 10 through 12 are cross-sectional views illustrating a method of manufacturing the light-emitting device package 100 according to example embodiments.

Referring to FIG. 10, the circuit board 110 is provided. The circuit board 110 may be a printed circuit board with circuit patterns formed inside and/or on the top.

The plurality of light-emitting devices 120 may be mounted on the circuit board 110. The plurality of light-emitting devices 120 may be mounted on the circuit board 110 using a flip chip method. For example, the plurality of light-emitting devices 120 may be mounted on the circuit board 110 via the adhesive layer 128 of FIG. 3. The first and second electrode pads 126b and 127b of the plurality of light-emitting devices 120 may be electrically connected to circuit patterns arranged on or inside the circuit board 110 by the adhesive layer 128.

The plurality of light-emitting devices 120 may be arranged to be spaced apart from each other with the first pitch P1 in the first horizontal direction X. For example, a center point of one light-emitting device 120 and a center point of another light-emitting device 120 adjacent thereto may be spaced apart by the first pitch P1. In some embodiments, the first pitch P1 may range from about 3 mm to about 100 mm. However, embodiments are not limited thereto.

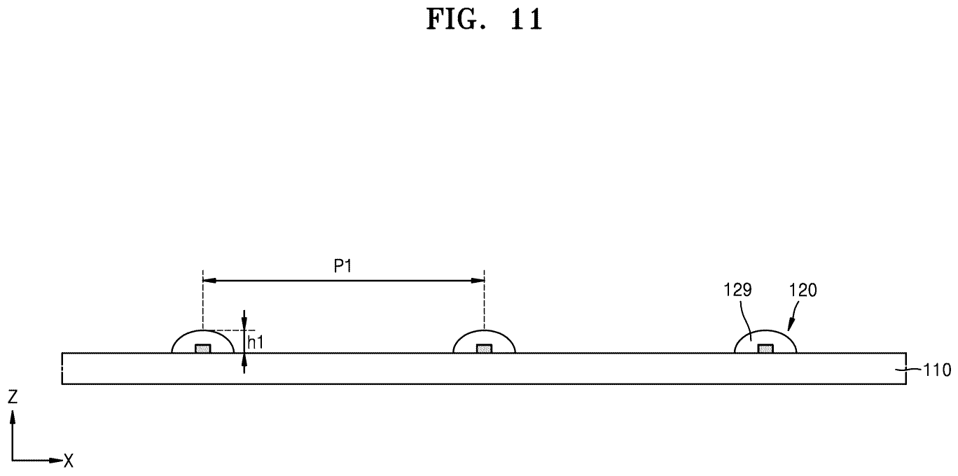

Referring to FIG. 11, the transparent resin layer 129 may be formed on the circuit board 110 to cover the plurality of light-emitting devices 120. In example embodiments, the transparent resin layer 129 may contact the semiconductor substrate 122 of the plurality of light-emitting devices 120.

The transparent resin layer 129 may include a resin in which a phosphor is dispersed or a resin that does not contain a phosphor. For example, the transparent resin layer 129 may include a phosphor film or a silicon resin.

In an exemplary process for forming the transparent resin layer 129, the transparent resin layer 129 may be formed on the circuit board 110 to cover the plurality of light-emitting devices 120 according to a liquid injection method or a spray method.

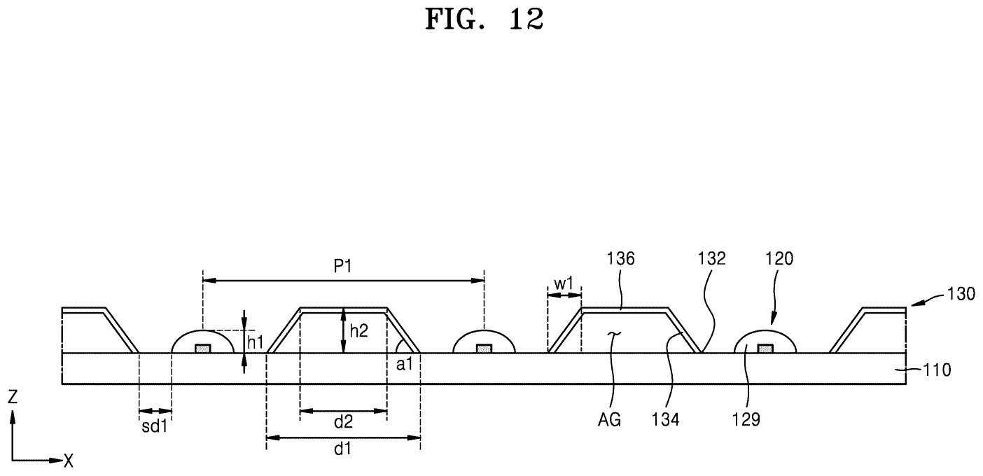

Referring to FIG. 12, the reflective sheet 130 may be attached onto the circuit board 110.

In some embodiments, the reflective sheet 130 may include a biaxially oriented polyester film, and the plurality of openings 132 may be formed by attaching the reflective sheet 130 in the form of a film to the circuit board 110 and removing a portion of the reflective sheet 130 according to a pressing method or the like. In some embodiments, the reflective sheet 130 and the circuit board 110 may be attached to each other by using an adhesive.

In some embodiments, the reflective sheet 130 may be formed using an injection-type process or press-type process. For example, the reflective sheet 130 including the plurality of openings 132, the plurality of inclined portions 134, and the flat extension portion 136 may be prepared by using an injection-type process or press-type process, and then the reflective sheet 130 may be attached to the circuit board 110.

Thereafter, the diffuser plate 140 (see FIG. 2) may be installed on the circuit board 110.

The light-emitting device package 100 may be completed using the above-described method.

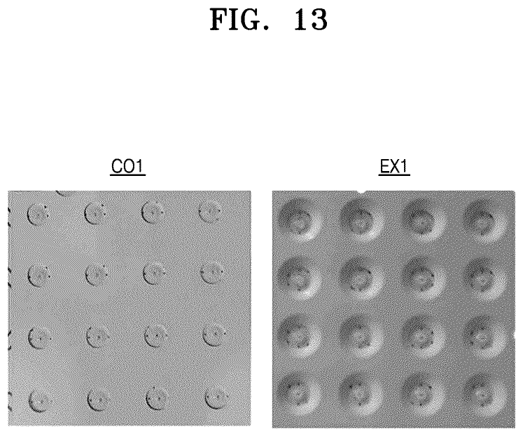

FIG. 13 illustrates optical images of light-emitting device packages according to example embodiments.

Referring to FIG. 13, Comparative example 1 CO1 shown on the left includes a light-emitting device mounted on a circuit board, and a planar reflective layer attached to the circuit board to surround the light-emitting device in a two-dimensional (2D) manner. Embodiment 1 EX1 shown on the right includes a light-emitting device mounted on a circuit board, and a reflective layer according to embodiments including a plurality of openings, a plurality of inclined portions, and a flat extension portion. The reflective sheet of Embodiment 1 EX1 shown in FIG. 13 has a similar shape to the reflective sheet 130 described above with reference to FIGS. 1 and 2.

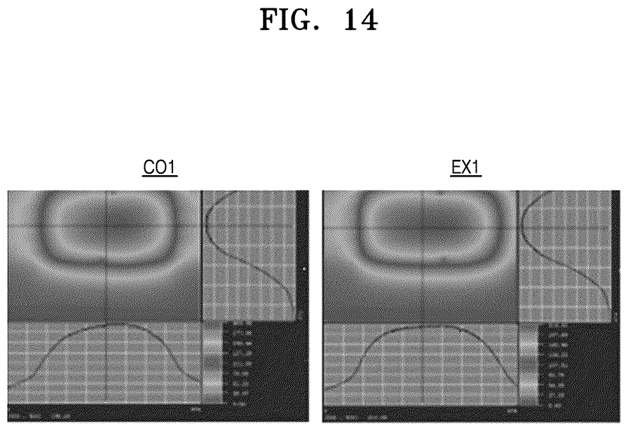

FIG. 14 is a graph showing luminances of the semiconductor device packages of FIG. 13.

Referring to FIG. 14, Comparative example 1 CO1 shown on the left shows a luminance center value of 198, and Embodiment 1 EX1 shown on the right shows a luminance center value of 210. Embodiment 1 EX1 showed a luminance value increased by approximately 7% or more compared to the first comparative example CO1. Compared to Comparative example 1 CO1, Embodiment 1 EX1 may be confirmed to exhibit higher luminance values in a wider area and more uniform luminance values.

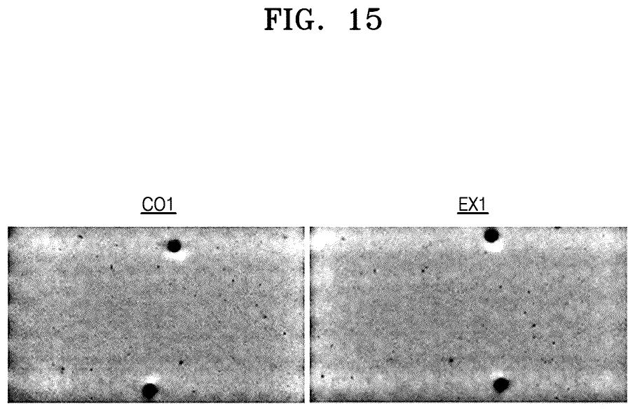

FIG. 15 illustrates optical images showing dark spots of the semiconductor device packages of FIG. 13.

Referring to FIG. 15, it may be seen that, compared to Comparative example 1 CO1 shown on the left, Embodiment 1 EX1 shown on the right showed fewer luminance non-uniform elements such as dark spots.

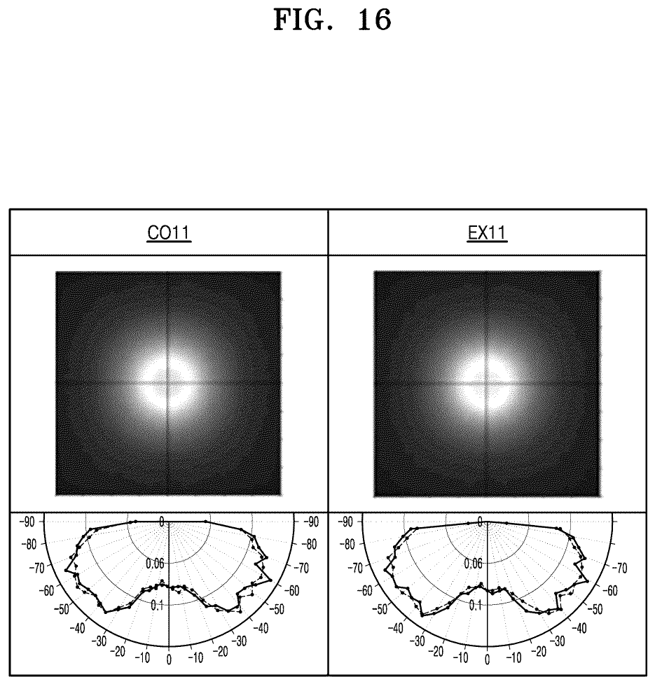

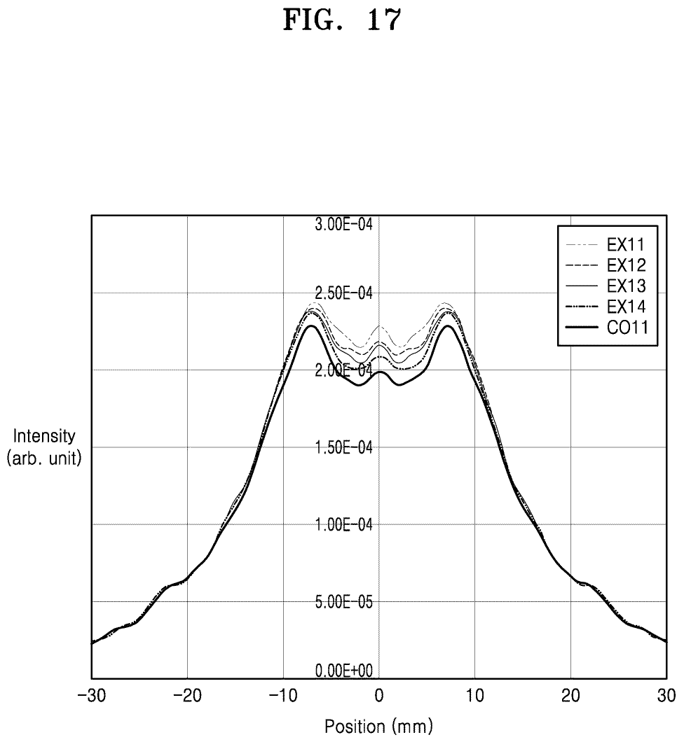

FIGS. 16 and 17 are graphs showing simulation results of respective far-field emission patterns of single chip packages.

FIG. 16 illustrates images and graphs showing the far-field emission patterns of the single chip packages.

In FIG. 16, Comparative example 11 CO11 shown on the left is a far-field emission pattern of a single chip package including a single light-emitting device and a planar reflective layer disposed around the single light-emitting device, and Embodiment 11 EX11 shown on the right is a far-field emission pattern of a single chip package including a single light-emitting device and a three-dimensional (3D) reflective sheet disposed around the single light-emitting device, the 3D reflective sheet including an opening, an inclined portion with an inclination angle of 10 degrees, and a flat extension portion.

As shown in FIG. 16, it may be confirmed that a luminance difference between a central area and a peripheral area of Embodiment 11 EX11 is less than a luminance difference between a central area and a peripheral area of Comparative example 11 CO11.

FIG. 17 is a graph showing luminances of a single chip package versus a variation in angle.

In FIG. 17, Embodiment 11 EX11 has an inclination angle of the inclined portion that is 10 degrees, Embodiment 12 EX12 has an inclination angle of an inclined portion that is 7.5 degrees, Embodiment 13 EX13 has an inclination angle of an inclined portion that is 5 degrees, and Embodiment 14 EX14 has an inclination angle of an inclined portion that is 2.5 degrees. Comparative example 11 CO11 was provided with a planar reflective layer, and corresponds to, for example, a case where the inclination angle of an inclined portion is 0 degrees. In the graph of FIG. 17, the x-axis represents a distance in a horizontal direction from a center point of a light-emitting device, and the y-axis represents luminance.

Referring to FIG. 17, Comparative example 11 CO11 exhibited a lowest luminance in the center area (at a spot where an x position is adjacent to 0 or at a spot between-2 mm and 2 mm in the horizontal direction) and a largest luminance at spots of −8 mm and 8 mm in the horizontal direction, and a difference between highest and lowest values of luminance was the largest. On the other hand, as the size of the inclination angle increases, a luminance value in the center area increased. For example, Embodiment 14 EX14 had a higher luminance value in the center area than Comparative example 11 CO11, Embodiment 13 EX13 had a higher luminance value in the center area than Embodiment 14 EX14, Embodiment 12 EX12 had a higher luminance value in the center area than Embodiment 13 EX13, and Embodiment 11 EX11 had a higher luminance value in the center area than Embodiment 12 EX12. In addition, as the size of the inclination angle increases, a difference between the highest and lowest values of luminance decreased. For example, Embodiment 11 EX11 had a smallest difference between the highest and lowest values of luminance.

In summary, as described above with reference to FIGS. 13 through 17, light-emitting device packages according to embodiments may exhibit higher luminance and fewer luminance non-uniform elements. Therefore, a backlight unit and a display device each employing a light-emitting device package may have excellent optical quality.

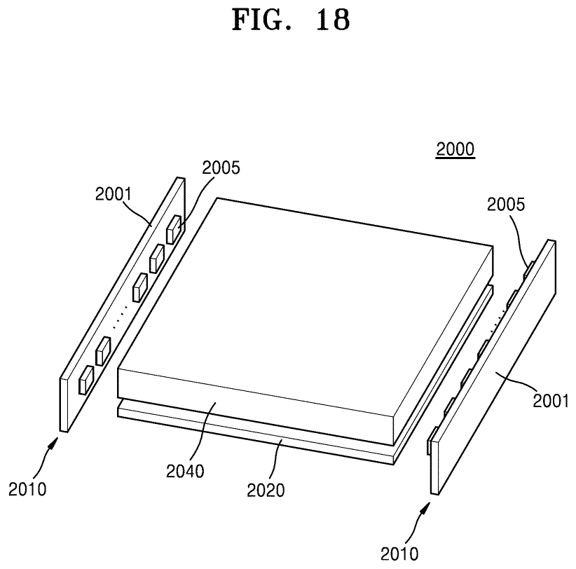

FIG. 18 is a schematic perspective view of a backlight unit including a light-emitting device package according to example embodiments.

Referring to FIG. 18, a backlight unit 2000 may include a light guide plate 2040 and light source modules 2010 provided at both sides of the light guide plate 2040. Furthermore, the backlight unit 2000 may further include a reflective plate 2020 disposed below the light guide plate 2040. The backlight unit 2000 according to the present embodiment may be an edge-type backlight unit. According to an embodiment, a light source module 2010 may be provided only at one side of the light guide plate 2040, or an additional light source module 2010 may be provided at another side of the light guide plate 2040. The light source module 2010 may include a printed circuit board 2001 and a plurality of light sources 2005 mounted on an upper surface of the printed circuit board 2001, and may include any of the light-emitting device packages 100, 100A, 100B, 100C, 100D, 100E, and 100F described above with reference to FIGS. 1 through 17.

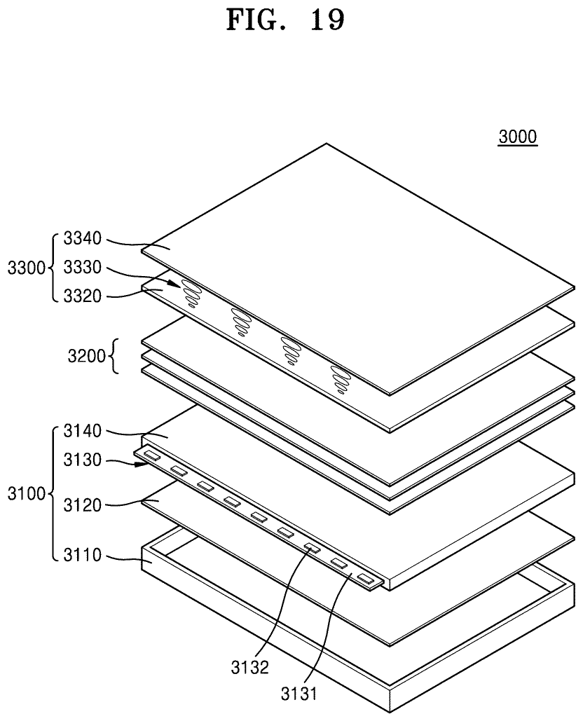

FIG. 19 is a schematic exploded perspective view of a display device including a light-emitting device package according to example embodiments.

Referring to FIG. 19, a display device 3000 may include a backlight unit 3100, an optical sheet 3200, and an image display panel 3300, such as a liquid crystal display (LCD) panel. The backlight unit 3100 may include a bottom case 3110, a reflective plate 3120, a light guide plate 3140, and a light source module 3130 provided on at least one side of the light guide plate 3140. The light source module 3130 may include a printed circuit board 3131 and light sources 3132.

In particular, the light sources 3132 may be side-view type light-emitting devices mounted on a side surface adjacent to a light-emitting surface. The light source module 3130 may include any of the light-emitting device packages 100, 100A, 100B, 100C, 100D, 100E, and 100F described above with reference to FIGS. 1 through 17. The optical sheet 3200 may include several types of sheets, such as sheets, prism sheets, or protective sheets.

The image display panel 3300 may display an image by using light emitted by the optical sheet 3200. The image display panel 3300 may include an array substrate 3320, a liquid crystal layer 3330, and a color filter substrate 3340. The array substrate 3320 may include pixel electrodes disposed in a matrix-like shape, thin-film transistors that apply driving voltages to the pixel electrodes, and signal lines for operating the thin-film transistors.

The color filter substrate 3340 may include a transparent substrate, a color filter, and a common electrode. The color filter may include filters for selectively transmitting light of particular wavelengths from white light emitted by the backlight unit 3100. The liquid crystal layer 3330 may be rearranged by an electric field formed between the pixel electrodes and the common electrode, thereby adjusting light transmittance. Light of which transmittance is adjusted may pass through the color filter of the color filter substrate 3340, thereby displaying an image. The image display panel 3300 may further include a driving circuit unit for processing image signals.

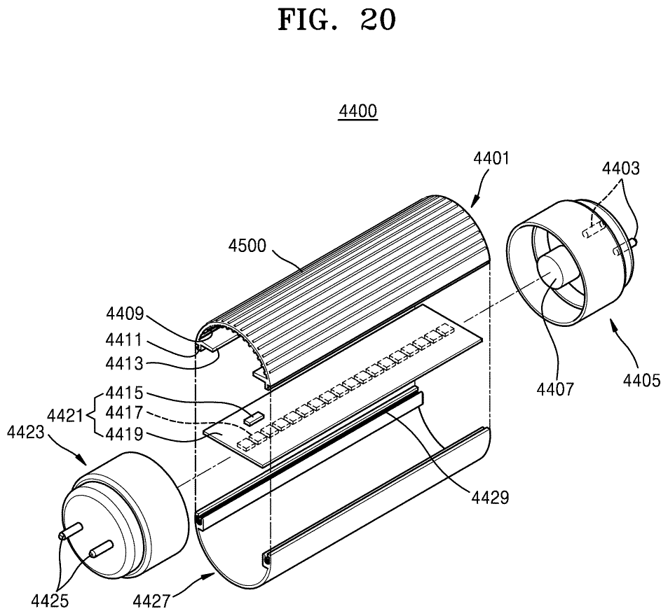

FIG. 20 is a schematic exploded perspective view of a bar-type illumination apparatus including a light-emitting device manufactured using a light-emitting device manufacturing method according to an example embodiment,

Referring to FIG. 20, an illumination apparatus 4400 includes a heat dissipation member 4401, a cover 4427, a light source module 4421, a first socket 4405, and a second socket 4423. A plurality of heat dissipating pins 4500 and 4409 may be disposed on the inner surface and/or the outer surface of the heat dissipation member 4401 as uneven structures, where the heat dissipating pins 4500 and 4409 may be designed to have one of various shapes at one of various intervals. A protruding supporter 4413 is disposed inside the heat dissipation member 4401. The light source module 4421 may be fixed by the supporter 4413. Locking hooks 4411 may be disposed at two opposite ends of the heat dissipating member 4401.

Locking grooves 4429 are disposed at the cover 4427, where the locking hooks 4411 of the heat dissipating member 4401 may be hook-combined with the locking grooves 4429. Locations of the locking grooves 4429 and the locking hooks 4411 may be reversed.

The light source module 4421 may include a light-emitting device array. The light source module 4421 may include a printed circuit board 4419, light sources 4417, and a controller 4415. The controller 4415 may store information for driving the light source 4417. Although not illustrated, the controller 4415 can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the controller 4415, and storage media or other suitable type of memory (e.g., such as, for example, RAM, ROM, programmable ROM (PROM), erasable programmable ROM (EPROM), electrically erasable programmable ROM (EEPROM), any type of tangible and non-transitory storage medium) where data and/or instructions can be stored. Circuit wires for driving the light sources 4417 may be disposed on the printed circuit board 4419. Furthermore, the printed circuit board 4419 may include components for driving the light sources 4417. The light source module 4421 may include the light-emitting device packages 100, 100A, 100B, 100C, 100D, 100E, and 100F described above with reference to FIGS. 1 through 17.

First and second sockets 4405 and 4423 are a pair of sockets and are attached to two opposite ends of the cylindrical cover unit consisting of the heat dissipation member 4401 and the cover 4427. For example, the first socket 4405 may include an electrode terminal 4403 and a power supply unit 4407, whereas a dummy terminal 4425 may be disposed at the second socket 4423. Furthermore, an optical sensor and/or a communication module may be embedded to either one of the first socket 4405 or the second socket 4423. For example, an optical sensor and/or a communication module may be embedded to the second socket 4423 including the dummy terminal 4425. In another example, an optical sensor and/or a communication module may be embedded to the first socket 4405 including the electrode terminal 4403.

According to a light-emitting package according to an embodiment, light emitted by a light-emitting device chip may be emitted with high luminance due to an inclined portion and a flat extension portion of a reflective sheet disposed on a circuit board 110, and occurrence of luminance non-uniform elements such as dark spots may be prevented. A backlight unit and a display device each employing a light-emitting device package may have excellent optical quality.

While the inventive concept has been particularly shown and described with reference to embodiments thereof, it will be understood that various changes in form and details may be made therein without departing from the spirit and scope of the following claims.

What is claimed is:

1. A light-emitting device package comprising:
a circuit board;
a light-emitting device mounted on the circuit board;
a reflective sheet disposed on the circuit board, the reflective sheet comprising:
an opening penetrating through the reflective sheet, wherein the light-emitting device is disposed within the opening,
an inclined portion surrounding the opening when viewed in the plan view, and being inclined at a first angle with respect to an upper surface of the circuit board, and
a flat extension portion surrounding the inclined portion when viewed in a plan view, and being parallel to the upper surface of the circuit board; and
a diffuser plate disposed at a first vertical distance from the upper surface of the circuit board,
wherein an air gap is disposed between the upper surface of the circuit board and the flat extension portion.

2. The light-emitting device package of claim 1, wherein the first angle is in a range of about 5 degrees to about 70 degrees.

3. The light-emitting device package of claim 1, wherein a separation distance between the opening and the light-emitting device is in a range of about 0.5 mm to about 1 mm.

4. The light-emitting device package of claim 1, wherein the first vertical distance is in a range of about 1 mm to about 300 mm.

5. The light-emitting device package of claim 1,
wherein the light-emitting device has a first height from the upper surface of the circuit board in a vertical direction perpendicular to the upper surface of the circuit board,
wherein the flat extension portion of the reflective sheet has a second height in the vertical direction from the upper surface of the circuit board, and
wherein the second height is greater than the first height.

6. The light-emitting device package of claim 1,
wherein a planar shape of the opening includes a circle, an oval, a hexagon, a square, or a rectangle with rounded corners, and
wherein a planar shape of the inclined portion includes a circle, an oval, a hexagon, a square, or a rectangle with rounded corners.

7. The light-emitting device package of claim 1,
wherein the reflective sheet includes a biaxially oriented polyester film, and
wherein the reflective sheet is attached onto the circuit board through an adhesive layer.

8. The light-emitting device package of claim 7, wherein the reflective sheet has a reflectivity of about 80% to about 100% and a transmittance of about 0 to about 20%.

9. The light-emitting device package of claim 1, wherein the light-emitting device comprises:
a semiconductor substrate;
a light-emitting stack including a first semiconductor layer, an active layer, and a second semiconductor layer sequentially arranged on the semiconductor substrate;
a first electrode electrically connected to the first semiconductor layer through a first connection electrode portion extending to an inside of the light-emitting stack;
a second electrode electrically connected to the second semiconductor layer; and
a transparent resin layer surrounding the semiconductor substrate and the light-emitting stack.

10. The light-emitting device package of claim 9, wherein the light-emitting device is configured to emit light in a range of about 415 nm to about 495 nm.

11. A light-emitting device package comprising:
a circuit board;
a reflective sheet disposed on the circuit board, the reflective sheet comprising:
a plurality of openings disposed apart from each other at a first interval in a first horizontal direction parallel to an upper surface of the circuit board and penetrating through the reflective sheet,
a plurality of inclined portions respectively surrounding the plurality of openings when viewed in the plan view, wherein each of the plurality of inclined portions is inclined at a first angle with respect to the upper surface of the circuit board and the plurality of inclined portions are arranged apart from each other at a second interval in the first horizontal direction, and
a flat extension portion surrounding the plurality of inclined portions when viewed in a plan view and being parallel to the upper surface of the circuit board, wherein the flat extension portion is spaced apart from the upper surface of the circuit board in a vertical direction perpendicular to the upper surface;
a plurality of light-emitting devices mounted on the circuit board and respectively disposed within the plurality of openings of the reflective sheet; and
a diffuser plate disposed at a first vertical distance from the upper surface of the circuit board.

12. The light-emitting device package of claim 11,
wherein the first angle ranges from about 5 degrees to about 70 degrees, and
wherein a separation distance between each of the plurality of openings and a light-emitting device corresponding to each opening is in a range of about 0.5 mm to about 1 mm.

13. The light-emitting device package of claim 11,
wherein each of the plurality of light-emitting devices has a first height from the upper surface of the circuit board in a vertical direction perpendicular to the upper surface of the circuit board,
wherein the flat extension portion of the reflective sheet has a second height in the vertical direction from the upper surface of the circuit board, and
wherein the second height is greater than the first height.

14. The light-emitting device package of claim 11,
wherein the plurality of light-emitting devices are arranged such that a distance between respective centers of the plurality of light-emitting devices is a first pitch, and
wherein a ratio of the first pitch to the first vertical distance is about 2 to about 10.

15. The light-emitting device package of claim 14,
wherein each of the plurality of inclined portions has a first width from a side wall of a corresponding one of the plurality of openings to a boundary line between the inclined portion and the flat extension portion, and
wherein the first width is about 5% to about 30% of the first pitch.

16. The light-emitting device package of claim 11,
wherein a planar shape of each of the plurality of openings is a circle, an oval, a hexagon, a square, or a rectangle with rounded corners, and
wherein a planar shape of each of the plurality of inclined portions is a circle, an oval, a hexagon, a square, or a rectangle with rounded corners.

17. The light-emitting device package of claim 11, wherein a first opening among the plurality of openings and a first inclined portion corresponding to the first opening among the plurality of inclined portions form a concentric circle.

18. The light-emitting device package of claim 11,
wherein each of the plurality of light-emitting devices comprises:
a semiconductor substrate;
a light-emitting stack including a first semiconductor layer, an active layer, and a second semiconductor layer sequentially arranged on the semiconductor substrate;
a first electrode electrically connected to the first semiconductor layer through a first connection electrode portion extending to an inside of the light-emitting stack;
a second electrode electrically connected to the second semiconductor layer; and
a transparent resin layer surrounding the semiconductor substrate and the light-emitting stack, and
wherein each of the plurality of light-emitting devices is configured to emit light in a range of about 415 nm to about 495 nm.

19. A light-emitting device package comprising:
a circuit board;
a plurality of light-emitting devices disposed on the circuit board and arranged in an array form;
a reflective sheet disposed on an upper surface of the circuit board, the reflective sheet comprising:
a plurality of openings penetrating through the reflective sheet, wherein the plurality of light-emitting devices are disposed within the plurality of openings, respectively,
a plurality of inclined portions respectively surrounding the plurality of openings when viewed in a plan view, wherein each of the plurality of inclined portions is inclined at a first angle with respect to the upper surface of the circuit board, and
a flat extension portion surrounding the plurality of inclined portions when viewed in the plan view and being parallel to the upper surface of the circuit board, wherein the flat extension portion is spaced apart from the upper surface of the circuit board in a vertical direction perpendicular to the upper surface; and
a diffuser plate disposed at a first vertical distance from the upper surface of the circuit board,
wherein an air gap is disposed between the flat extension portion and the upper surface of the circuit board.

20. The light-emitting device package of claim 19,
wherein the plurality of light-emitting devices are arranged such that a distance between respective centers of the plurality of light-emitting devices is a first pitch, and
wherein a ratio of the first pitch to the first vertical distance is about 2 to about 10.
